(19) United States
(12) Patent Application Publication
(10) Pub. No.: US 2025/0355477 A1
(43) Pub. Date: Nov. 20, 2025

(54) METHOD AND APPARATUS WITH BATTERY STATE OF CHARGE DETERMINATION

(71) Applicant: Samsung Electronics Co., Ltd., Suwon-si (KR)

(72) Inventors: Sagar BHARATHRAJ, Bengaluru (IN); Shashishekara Parampalli ADIGA, Bengaluru (IN)

(73) Assignee: Samsung Electronics Co., Ltd., Suwon-si (KR)

(21) Appl. No.: 19/188,712

(22) Filed: Apr. 24, 2025

(30) Foreign Application Priority Data
May 20, 2024 (IN) 202441039330
Aug. 31, 2024 (IN) 202441039330
Dec. 4, 2024 (KR) 10-2024-0178914

(51) Int. Cl. G06F 1/26; G01R 31/382; H01M 10/42

(52) U.S. Cl. CPC G06F 1/26; G01R 31/382; H01M 10/425; H01M 2010/4271

(57) ABSTRACT

A processor-implemented method including determining an equilibrium ion-concentration value of a battery by correlating initial ion-concentration values, at a beginning of a rest period of the battery, over a plurality of surfaces of a battery electrode particle of the battery, and a size of the battery electrode particle, generating, at an instance of interest, a transient ion-concentration profile over the plurality of surfaces, based on a configuration of the battery and the initial ion-concentration values, and determining a state of charge (SoC) of the battery at the instance of interest by correlating the equilibrium ion-concentration value and the transient ion-concentration profile.

### CROSS-REFERENCE TO RELATED APPLICATIONS

This application claims the benefit under 35 USC § 119 (a) of Indian Patent Application number 202441039330 filed on May 20, 2024, and Indian Patent Application number 202441039330 filed on Aug. 31, 2024, in the Indian Patent Office, and Korean Patent Application No. 10-2024-0178914 filed on Dec. 4, 2024, in the Korean Intellectual Property Office, the entire disclosures of which are incorporated by reference herein for all purposes.

### BACKGROUND

### 1. Field

The following relates to a method and apparatus with battery state of charge determination.

### 2. Description of Related Art

A battery may typically perform an operation of providing a necessary amount of power for a device to operate effectively. For example, the battery may supply power to components of the device and an electronic circuit. A rechargeable battery is an example of an electric battery that may be charged, discharged to a load, and then recharged using an external power source.

A lithium-ion (Li-ion) battery is an example of a rechargeable battery. The Li-ion battery may have high energy density and a long lifespan and may be used in various electronic devices. The state of charge (SoC) of the battery may typically be expressed as a percentage. For example, an SoC value of 0% indicates that the battery is fully discharged, while an SoC value of 100% indicates that the battery is fully charged. Accurately determining the SoC value of the battery is critical to the safety and performance of the battery while supplying power to an electronic device.

The battery may be installed with models or on-board systems such as a battery management system (BMS) to estimate an SoC value. These systems and models may estimate an SoC value, based on monitoring a battery voltage and mapping the monitored voltage to a predetermined SoC value and a voltage table. In a typical BMS, a plurality of SoC values may be mapped to the same voltage value of the battery. Therefore, it is difficult to accurately estimate an SoC value in typical BMS's.

Additionally, the SoC voltage profile may generally correspond to a flat line. Typically, for the most popular lithium iron phosphate (LFP)-based battery, the change in voltage with changing SoC value may be a flat line. For example, an SoC-voltage profile of an LFP battery may be substantially flat and the voltage may vary within a narrow range of 3.2 volts (V) to 3.3 V for SoC values between 1% and 90%. Therefore, since the typical BMS may have multiple SoC values corresponding to the same voltage value, the reliability of the estimated SoC value may be low. This LFP battery is very commonly used in electric vehicles. An LFP battery mounted on an electric vehicle may have a long rest-period after being used, so it is typically preferable, for the performance of the electric vehicle and for battery performance, to be able to accurately estimate an SoC value.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a processor-implemented method including determining an equilibrium ion-concentration value of a battery by correlating initial ion-concentration values, at a beginning of a rest period of the battery, over a plurality of surfaces of a battery electrode particle of the battery, and a size of the battery electrode particle, generating, at an instance of interest, a transient ion-concentration profile over the plurality of surfaces, based on a configuration of the battery and the initial ion-concentration values, and determining a state of charge (SoC) of the battery at the instance of interest by correlating the equilibrium ion-concentration value and the transient ion-concentration profile.

The determining of the equilibrium ion-concentration value of the battery may include generating an initial ion-concentration profile of an ion concentration over the plurality of surfaces of the battery electrode particle.

The determining of the equilibrium ion-concentration value of the battery may include determining an average of the initial ion-concentration profile corresponding to a volume of the battery electrode particle.

The determining of the equilibrium ion-concentration value of the battery may include generating, via a battery management system (BMS) of the battery, an initial ion-concentration profile of ion-concentration values over the plurality of surfaces of the battery electrode particle at the beginning of the rest period of the battery and determining, via the BMS, the equilibrium ion-concentration value by correlating the size of the battery electrode particle and the initial ion-concentration profile.

The generating of the transient ion-concentration profile may include determining a diffusivity corresponding to the configuration of the battery and determining, at the instance of interest, transient ion-concentration values over the plurality of surfaces by correlating the size of the battery electrode particle, the diffusivity, an elapsed time after the beginning of the rest period, and the equilibrium ion-concentration value.

The method may include detecting an operating condition of the battery by comparing a current of the battery with a preset current value, and the operating condition may correspond to one of a rest condition of the battery, a charging condition of the battery, and a discharging condition of the battery.

The method may include determining a rest period SoC of the battery at the instance of interest, and the determining of the rest period SoC of the battery may include generating, at the beginning of the rest period of the battery, ion-concentration values over a surface of the battery electrode particle, determining the equilibrium ion-concentration value by correlating the ion-concentration values and the size of the battery electrode particle, generating, at the instance of interest, a transient profile of the ion-concentration values over the surface of the battery electrode particle, based on a configuration of the battery and an elapsed time after the beginning of the rest period, and determining the SoC of the battery at the instance of interest by correlating the generated transient profile and the equilibrium ion-concentration value.

The method may include determining an equilibrium SoC value in the rest period of the battery, the determining of the equilibrium SoC value may including determining, at the beginning of the rest period of the battery, ion-concentration values over the surfaces of the electrode particle of the battery and determining the equilibrium SoC value by correlating sizes of the surfaces of the battery electrode particle and the ion-concentration values.

The method may include determining a diffusivity of the battery, the determining of the diffusivity of the battery including determining the initial ion-concentration values over the plurality of surfaces of the battery electrode particle and determining the diffusivity of the battery by correlating the initial ion-concentration values, an elapsed time after the beginning of the rest period of the battery, and a size of the battery electrode particle.

The method may include determining a diffusivity of the battery, determining, based on a predetermined electrochemical-thermal (ECT) model, an open circuit potential (OCP) of the battery, calculating a first diffusivity of the battery responsive to the battery being in the rest period at the instance of interest and the SoC and the OCP being obtained after the beginning of the rest period, comparing an amount of time elapsed after the beginning of the rest period with a predetermined threshold value, calculating a second diffusivity of the battery in response to the elapsed time being greater than the predetermined threshold value, and changing a frequency of obtaining the SoC and the OCP in response to an error between the first diffusivity and the second diffusivity being greater than a preset value.

In a general aspect, here is provided a non-transitory computer-readable storage medium storing instructions that, when executed by a processor, cause the processor to perform the method.

In a general aspect, here is provide an electronic device including processors configured to execute instructions and a memory storing the instructions, and execution of the instructions configures the processors to determine an equilibrium ion-concentration value of a battery by correlating initial ion-concentration values, at beginning of a rest period of the battery, over a plurality of surfaces of a battery electrode particle of the battery, and a size of the battery electrode particle, generate, at an instance of interest, a transient ion-concentration profile over the plurality of surfaces, based on a configuration of the battery and the initial ion-concentration values, and determine a state of charge (SoC) of the battery at the instance of interest by correlating the determined equilibrium ion-concentration value and the transient ion-concentration profile.

The determining the equilibrium ion-concentration value may include generating an initial ion-concentration profile of ion-concentration values over the plurality of surfaces of the battery electrode particle.

The determining the equilibrium ion-concentration value may include determining an average of the initial ion-concentration profile corresponding to a volume of the battery electrode particle.

The determining the equilibrium ion-concentration value may include generating, via a battery management system (BMS) of the battery, an initial ion-concentration profile of the ion-concentration values over the plurality of surfaces of the battery electrode particle at the beginning of the rest period of the battery and determining the equilibrium ion-concentration value by correlating, via the BMS, the size of the battery electrode particle and the initial ion-concentration profile.

The generating the transient ion-concentration profile may include determining a diffusivity corresponding to the configuration of the battery and determining, at the instance of interest, transient ion-concentration values over the plurality of surfaces by correlating the size of the battery electrode particle, the diffusivity, an elapsed time after the beginning of the rest period and the equilibrium ion-concentration value.

The processors may be further configured to detect an operating condition of the battery by comparing a current of the battery with a preset current value and the operating condition may correspond to one of a rest condition of the battery, a charging condition of the battery, and a discharging condition of the battery.

The determining the equilibrium ion-concentration value may include generating, at the beginning of the rest period of the battery, ion-concentration values over a surface of the battery electrode particle and determining the equilibrium ion-concentration value by correlating the ion-concentration values and a size of the battery electrode particle, the generating the transient ion-concentration profile may include generating, at the instance of interest, a transient profile of the ion-concentration values over the surface of the battery electrode particle, based on the configuration of the battery and an elapsed time after the beginning of the rest period, the determining the SoC may include determining the SoC of the battery, at the instance of interest, by correlating the equilibrium ion concentration value and the transient profile, and the processors may be further configured to determine a rest period SoC of the battery at the instance of interest.

The determining the equilibrium ion-concentration value may include determining ion-concentration values over surfaces of an electrode particle of the battery at the beginning of the rest period of the battery and the determining the SoC may include determining an equilibrium SoC in the rest period of the electronic device by correlating sizes of the surfaces of the battery electrode particle and the ion-concentration values.

The determining the equilibrium ion-concentration value may include determining the initial ion-concentration values over a plurality of surfaces of the battery electrode particle and the processors may be further configured to determine a diffusivity of the battery by correlating the initial ion-concentration values, an elapsed time, and a size of the battery electrode particle. Other features and aspects will be apparent from the following detailed description, the drawings, and the claims.

### BRIEF DESCRIPTION OF THE DRAWINGS

FIG. 1A illustrates an example battery apparatus according to one or more embodiments.

FIG. 1B illustrates an example battery electrode particle of a battery and an ion-concentration profile according to one or more embodiments.

FIG. 1C illustrates an example profile associated with a battery electrode particle according to one or more embodiments.

FIG. 2 illustrates an example method for determining a state of charge (SoC) of a battery at an instance of interest according to one or more embodiments.

FIG. 3 illustrates an example method for an electronic device to determine a rest period SoC value of a battery at an instance of interest according to one or more embodiments.

FIG. 4 illustrates an example method for an electronic device to determine an equilibrium SoC value according to one or more embodiments.

FIG. 5 illustrates an example method for an electronic device to determine a diffusivity of a battery according to one or more embodiments.

FIG. 6 illustrates an example electronic device for determining an SoC value of a battery at an instance of battery according to one or more embodiments.

FIG. 7 illustrates an example electronic device according to one or more embodiments.

Throughout the drawings and the detailed description, unless otherwise described or provided, it may be understood that the same drawing reference numerals refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

Estimating an SoC value with other typical systems may require a large amount of computations and a large number of variables and data for processing. Therefore, in these typical systems the performance of the BMS may degrade because the typical BMS's are unreliable, inconsistent, and impose an undesirable load on the BMS when estimating an SoC value.

Additionally, an accurate estimation of the solid phase diffusivity of the battery is desired for battery characterization. On the other hand, examples of typical BMS's, such as galvanostatic intermittent titration technique (GITT), has a disadvantage of relying on doubtful assumptions and requiring a special probe to measure diffusivity.

Therefore, there is a typically a desire for an electronic device and a method that may overcome one or more of the issues in typical BMS's as described above.

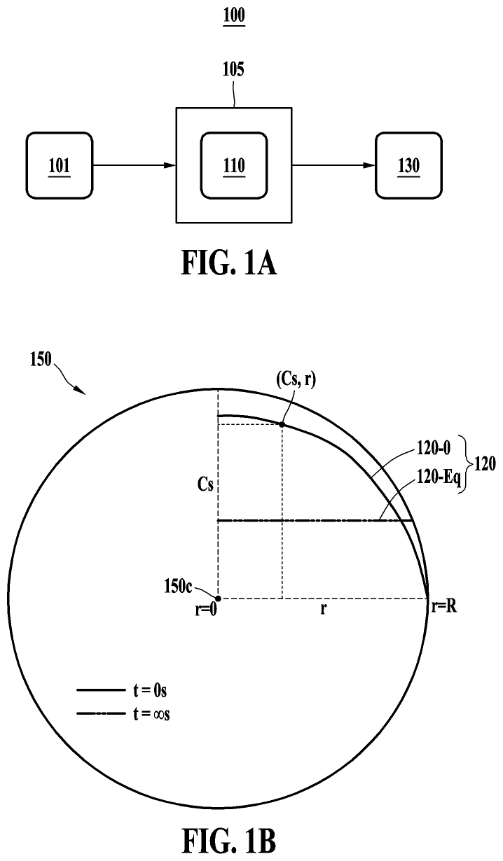

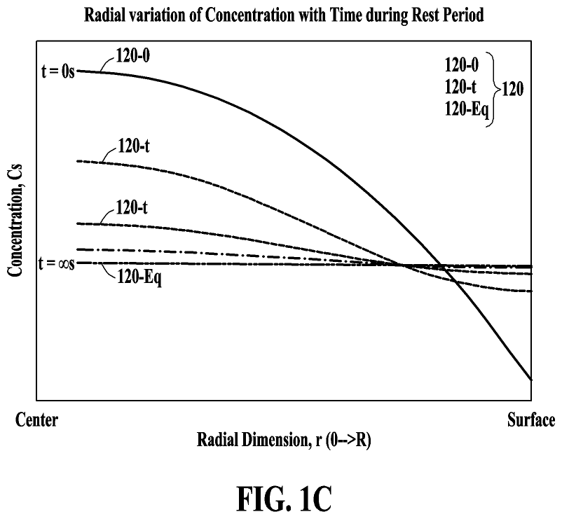

FIG. 1A illustrates an example battery apparatus according to one or more embodiments

Referring to FIG. 1A, in a non-limiting example, a battery apparatus 100 may include a battery 105, such as a rechargeable battery. For example, the battery 105 may include a battery pack including a plurality of cells or a single cell. A power supply device 101 may charge the battery 105. A load 130 may use power stored in the battery 105. The load 130 may be an electric vehicle. In this case, the battery 105 may be used as a driving force to move the electric vehicle. Therefore, an SoC of the battery 105 may change through repeated charging and discharging.

The battery 105 may be a lithium-ion (Li-ion) battery. For example, the battery 105 may include a lithium iron phosphate (LiFePO) battery or a lithium ferrophosphate (LFP) battery. An LFP battery is a type of Li-ion battery that uses LFP as the cathode of the battery 105 and a graphitic carbon electrode as the anode of the battery 105.

In an example, the battery apparatus 100 may include a battery management system (BMS) 110. The BMS 110 may be an electronic device (e.g., a system) having a processor and a memory that manages the battery 105, including estimating and monitoring the condition and state of the battery 105, such as a state of health (SoH) and an SoC. The BMS 110 may be configured to report and calculate data related to the battery 105.

FIG. 1B illustrates an example battery electrode particle and an ion-concentration profile according to one or more embodiments.

Referring to FIG. 1B, in a non-limiting example, the battery electrode particle 150 (hereinafter, a “particle” 150) is an electrode of a battery (e.g., the battery 105 of FIG. 1A). The battery electrode particle 150 includes an illustration of an ion-concentration profile 120 (hereinafter, a “profile” 120) related to the particle 150. The particle 150 may exhibit a spherical shape having an outer surface radius (r) having a value R. For example, FIG. 1B illustrates a cross-section of the particle 150 through a plane passing through a center 150c of the particle 150, and the cross-section of the particle 150 may be spherical.

The profile 120 may be a profile of ion-concentration values over an electrode surface of the battery (e.g., the battery 105 of FIG. 1A). For example, the profile 120 may correspond to the distribution of the ion-concentration values at a predetermined point on the electrode surface. As illustrated in FIG. 1B, the profile 120 may include a profile 120-0 and a profile 120-Eq. For example, the profile 120-0 may be a profile of ion-concentration values at a beginning instance of a rest period of the battery. For example, for a curved surface of the particle 150 denoted by a radius “r”, an ion-concentration value may be denoted by the coordinates (Cs, r). The profile 120-0 may be a plot of ion-concentration values with respect to the radius of the particle 150.

In an example, the profile 120-Eq may include a profile of ion-concentration values (Cs-s) of Li-ions over the surface of the particle 150 at an instance when the battery 105 reaches an equilibrium state. The battery (e.g., the battery 105 of FIG. 1A) may reach an equilibrium state after a substantial amount of time elapses after the beginning of the rest period. In this case, a substantial amount of time may vary depending on various factors including the initial SoC of the battery, the SoH of the battery, the lifespan of the battery, and the ambient conditions of the battery. Theoretically, a battery may reach an equilibrium state after an infinite amount of time, but in practice, a battery may reach an equilibrium state after 30 to 45 minutes. In other words, the profile 120-Eq may correspond to a flat line indicating that ion-concentration values are the same and constant at all points of the particle 150.

FIG. 1C illustrates an example profile associated with a battery electrode particle according to one or more embodiments.

Referring to FIG. 1C, in a non-limiting example, a graph 100G of the profile 120 associated with the particle 150 is illustrated. A transient ion-concentration profile 120-t of ion-concentration values (Cs-t) is illustrated at an instance of interest over a plurality of surfaces of the particle 150. In this case, the instance of interest may be an instance after the beginning of the rest period of the battery (e.g., the battery 105 of FIG. 1A) at which the SoC value of the battery (e.g., the battery 105 of FIG. 1A) has to be determined. For example, the instance of interest may be a time t when a user attempts to initiate an operation of a device (e.g., the load 130 of FIG. 1) connected to the battery (e.g., the battery 105 of FIG. 1A). The SoC value of the battery (e.g., the battery 105 of FIG. 1A) is of particular relevance during the instance of interest.

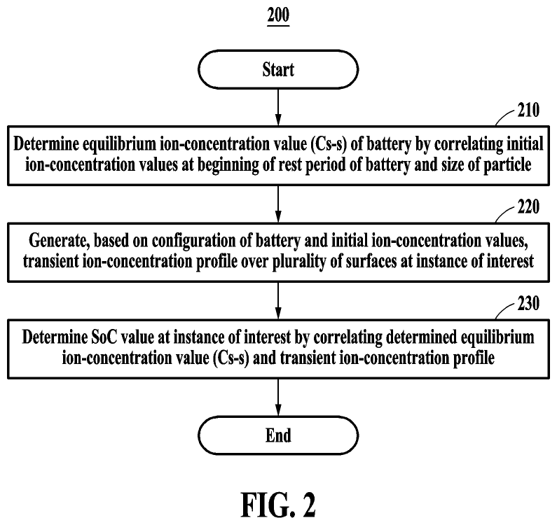

FIG. 2 illustrates an example method for determining a state of charge (SoC) of a battery at an instance of interest according to one or more embodiments.

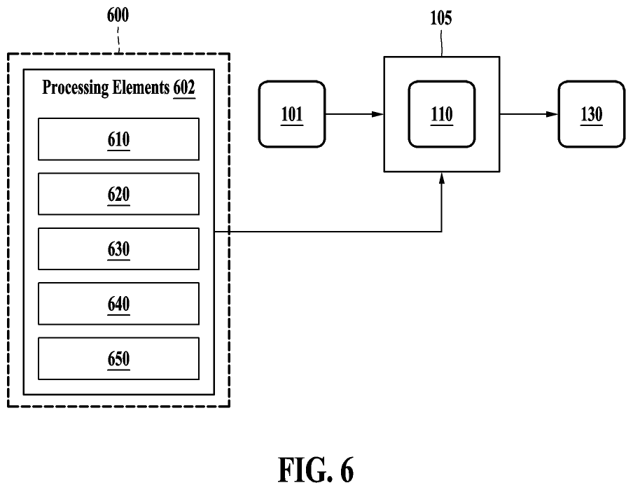

Referring to FIG. 2 in a non-limiting example, a method 200 in which an electronic device (e.g., a system or electronic device 600 of FIG. 6) determines an SoC value of a battery at an instance of interest. The method 200 may include operations 210 to 230 of FIG. 2. Hereinafter, the instance of interest may include an instance after the beginning of a rest period of the battery (e.g., the battery 105 of FIG. 1A). The rest period may be a period during which the battery (e.g., the battery 105 of FIG. 1A) is included in an open rest condition (e.g., when a battery current is zero) or a float rest condition (e.g., when a constant battery terminal voltage is maintained).

An electronic device may detect an operating condition of the battery by comparing a current flowing through a terminal of the battery (e.g., the battery 105 of FIG. 1A) to a preset current value. The operating condition of the battery may be one of a rest condition of the battery, a charging condition of the battery, and a discharging condition of the battery. For example, the electronic device may compare the current across the terminals of the battery to a preset current value to determine the beginning of a rest period associated with the battery. The preset current value may vary depending on the configuration of the battery. For example, the preset current value may include 0.01 amperes, 0.005 amperes, and the like.

In an example, in operation 210, the electronic device may determine an equilibrium ion-concentration value (Cs-s) of the battery by correlating initial ion-concentration values at the beginning of a rest period of the battery (e.g., the battery 105 of FIG. 1A) and the size of the particle (e.g., the particle 150 of FIG. 1B). The initial ion-concentration values may be concentration values at the beginning of the rest period and may be determined over a plurality of surfaces of the particle (e.g., the particle 150 in FIG. 1B). The size of the particle may correspond to the dimension of the particle, and the electronic device may calculate, based on the dimension, the surface area of the particle. For example, the particle may be spherical, and the size of the particle may correspond to the radius of the particle.

Additionally, in operation 210, the electronic device may generate an initial ion-concentration profile, such as a profile (e.g., the profile 120-0 of FIG. 1B) of ion-concentration values over the plurality of surfaces of the particle (e.g., the particle 150 of FIG. 1B). For example, the electronic device may correlate the initial ion-concentration values and the size of the particle, based on determining an average of the initial ion-concentration profile (e.g., the profile 120-0 of FIG. 1B) corresponding to the volume of the particle. In this regard, although FIG. 1B illustrates a cross-section of a particle, an ion-concentration value represented as a point (e.g., (Cs,r)) may correspond to an ion-concentration value for a point on the surface of a spherical particle (e.g., the particle 150 of FIG. 1B) with a radius of “r”.

For example, in operation 210, the electronic device may generate the initial ion-concentration profile (e.g., the profile 120-0 of FIG. 1B) of the particle (e.g., the particle 150 of FIG. 1B) via a BMS (e.g., the BMS 110 of FIG. 1A) of the battery at the beginning of the rest period of the battery (e.g., the battery 100 of FIG. 1A). Subsequently, the electronic device may correlate the size of the particle (e.g., the particle 150 of FIG. 1B) and the initial ion-concentration profile (e.g., the profile 120-0 of FIG. 1B) via the BMS to determine the equilibrium ion concentration value (Cs-s).

In an example, the electronic device may determine the equilibrium ion-concentration value (Cs-s) of the battery (e.g., the battery 100 of FIG. 1A), based on Equation 1 below.

$$( \frac{1}{{r}^{2}} ) D [ \frac{\partial }{\partial r} ( {r}^{2} \frac{\partial {Cs}_{s}}{\partial r} ) ] = 0 \qquad Equation 1$$

In Equation 1 above, r may denote the radius of the particle (e.g., the particle 150 of FIG. 1B) of the battery (e.g., the battery 105 of FIG. 1A). In addition, D may denote the diffusivity of the battery (e.g., the battery 100 of FIG. 1A). Next, Csₛ may denote the ion-concentration value on the surface of the particle (e.g., the particle 150 of FIG. 1B) in an equilibrium state. For reference, Csₛ may also be denoted by (Cs-s).

In an example, a boundary condition (BC), as expressed in Equation 2, may apply to Equation 1.

$$BC : 1 ) \frac{\partial Cs}{\partial r} = 0 @ all r ; \qquad Equation 2$$

$$BC : 2 ) Cs = Cs ( r ) @ t = 0$$

In an example, an ion-concentration value (Csₛ=Cₛ₋ₛ) at equilibrium of the particle (e.g., the particle 150 of FIG. 1B) may be calculated based on Equation 3 below.

$${Cs}_{s} = \frac{A}{r} + B \qquad Equation 3$$

In an example, in Equation 3, A and B may denote constants that may be determined by using Equation 2 above as Equation 4 below.

$$BC 1 \to \frac{\partial Cs}{\partial r} = - \frac{A}{{r}^{2}} = 0 \to A = 0 \qquad Equation 4$$

$$BC 2 \to {Cs}_{s} = B = ( \frac{{\int }_{r = 0}^{r = R} 4 π Cs ( r , t = 0 ) {r}^{2} dr}{\frac{4}{3} π {R}^{3}} ) \to {Cs}_{s} = \frac{3}{{R}^{3}} {\int }_{r = 0}^{r = R} Cs ( r , t = 0 ) {r}^{2} dr$$

In Equation 4, Csₛ may denote the ion-concentration value (Csₛ=Cs-s) in the equilibrium state of the particle (e.g., the particle 150 of FIG. 1B). As expressed in Equation 4, the electronic device may calculate the ion-concentration value (Csₛ=Cs-s) in the equilibrium state as a volumetric average of ion-concentration values over the surface of the particle (e.g., the particle 150 of FIG. 1B) at the beginning of a rest period.

In an example, in operation 220, the electronic device (e.g., a system) may generate a transient ion-concentration profile (e.g., the profile 120-t of FIG. 1C) of the ion-concentration values (Cs-t) over the plurality of surfaces of the particle (e.g., the particle 150 of FIG. 1B) at the instance of interest. In this case, the instance of interest may be a moment after the beginning of the rest period of the battery, which is the point in time at which an SoC value of the battery (e.g., the battery 105 of FIG. 1A) is to be determined. For example, the instance of interest may be a point in time (time=t) when a user desires to initiate an operation of a device (e.g., the load 130 of FIG. 1A) connected to the battery. Therefore, at the instance of interest, it may be of particular desirability to accurately determine the SoC value of the battery.

The electronic device may generate a transient ion-concentration profile (e.g., the profile 120-t of FIG. 1C), based on a configuration of the battery and an initial ion-concentration value (Cs-0). In an example, the electronic device may calculate the ion-concentration value (Cs-t) at the instance of interest, based on Equation 5 below.

$$\frac{\partial {Cs}_{t}}{\partial t} = ( \frac{1}{{r}^{2}} ) D [ \frac{\partial }{\partial r} ( {r}^{2} \frac{\partial {Cs}_{t}}{\partial r} ) ] \qquad Equation 5$$

In Equation 5, r may denote the radius of the particle (e.g., the particle 150 of FIG. 1B) of the battery (e.g., the battery 105 of FIG. 1A). In Equation 5, D may denote the diffusivity of the battery (e.g., the battery 100 of FIG. 1A). In addition, Csₜ may denote ion-concentration values on the surface of the particle (e.g., the particle 150 of FIG. 1B) at the instance of interest. For reference, Csₜ may also be denoted by (Cₛ₋ₜ).

In an example, the electronic device may apply a BC, as expressed in Equation 6, to Equation 5.

$$BC : \frac{\partial {Cs}_{t}}{\partial r} {\vert}_{t \geq 0} = 0 @ r = 0 , R ; and \qquad Equation 6$$

$$Initial Condition ( IC ) : {Cs}_{t} = Cs ( r , t = 0 ) @ t = 0$$

In an example, the electronic device may apply scaling, as expressed in Equation 7, to Equation 5 above.

$${r}^{*} = \frac{r}{R} ; {t}^{*} = \frac{t}{τ} = \frac{t}{{R}^{2} / D} \qquad Equation 7$$

Therefore, the electronic device may obtain Equation 8 based on applying Equation 7 to Equation 5.

$$\frac{\partial {Cs}_{t}}{\partial {t}^{*}} = ( \frac{1}{{r}^{* 2}} 〉 [ \frac{\partial }{\partial {r}^{*}} ( {r}^{* 2} \frac{\partial {Cs}_{t}}{\partial {r}^{*}} ) ] \qquad Equation 8$$

Based on Equation 8 above, the electronic device may transform the BC of Equation 6 into the BC of Equation 9 below.

$$BC : \frac{\partial {Cs}_{t}}{\partial r} {\vert}_{t \geq 0} = 0 @ {r}^{*} = 0 , 1 \& \qquad Equation 9$$

$$IC : {Cs}_{t} = Cs ( {r}^{*} , {t}^{*} = 0 ) - {( {Cs}_{s} ( r ) @ t )}^{*} = 0$$

Equation 9 above may be expressed as Equation 10 in a variable separable form.

$${Cs}_{t} ( {r}^{*} , {t}^{*} ) = M ( {r}^{*} ) \times N ( {t}^{*} ) \qquad Equation 10$$

The electronic device may derive Equation 11 below based on applying Equation 10 to Equation 8 above.

$$( \frac{1}{N} ) \frac{\partial N}{\partial {t}^{*}} = ( \frac{1}{M} ) ( \frac{1}{{r}^{* 2}} ) [ \frac{\partial }{\partial r} ( {r}^{* 2} \frac{\partial M}{\partial {r}^{*}} ) ] = - {γ}^{2} \qquad Equation 11$$

In Equation 11, an equation corresponding to a spatial part may be expressed as Equation 12 below.

$${r}^{* 2} \frac{{\partial }^{2} M}{\partial {r}^{* 2}} + 2 {r}^{*} \frac{θ M}{\partial {r}^{*}} + {γ}^{2} {r}^{* 2} M = 0 \qquad Equation 12$$

The solution to the differential equation for Equation 12 may be derived from Equation 13 below.

$$M ( {r}^{*} ) = \frac{K Sin ( γ {r}^{*} )}{{r}^{⋆}} + \frac{M Cos ( γ {r}^{⋆} )}{{r}^{⋆}} \qquad Equation 13$$

In Equation 13, under a first BC, the electronic device may set M=0. In addition, in Equation 13, under a second BC, the electronic device may derive Equation 14 by setting γ=tan(γ).

$$( \frac{1}{N} ) \frac{\partial N}{\partial {t}^{*}} = - {( \frac{( 2 n + 1 ) π}{2} )}^{2} \qquad Equation 14$$

The electronic device may derive a root corresponding to Equation 15 below from Equation 14.

$$N ( {t}^{*} ) = {e}^{- {γ}_{n}^{2} {t}^{⋆}} = {e}^{- ( {( ( 2 n + 1 ) π / 2 )}^{2} {t}^{*} )} \qquad Equation 15$$

The electronic device may determine a diffusivity value for the configuration of the battery (e.g., the battery 105 of FIG. 1A) in operation 220. The diffusivity of a predetermined configuration of the battery may remain the same. For example, the diffusivity for the predetermined configuration of the battery may be determined based on a galvanostatic/potentio-static intermittent titration technique (GITT/PITT), electrochemical impedance spectroscopy (EIS), an internal heating method, a step change method, and a heat stored method. Subsequently, in operation 230, the electronic device may generate a transient ion-concentration profile (e.g., the profile 120-t of FIG. 1C) by correlating the size of the particle (e.g., the particle 150 of FIG. 1B), determined diffusivity, a time elapsing after the beginning of a rest period, and the equilibrium ion-concentration value (Cs-s).

The electronic device may obtain Equation 16 below based on combining Equations 14 and 15 above and removing the scaling according to Equation 7 from the combined equation.

$$\begin{matrix}C {s}_{t} ( r , t ) = Cs ( r , t ) - C {s}_{s} ( r ) \\ = {\sum }_{n = 1}^{∞} ( \frac{R {K}_{n}}{r} ) {e}^{- ( \frac{{( \frac{( 2 n + 1 ) π}{2} )}^{2} D t}{{R}^{2}} )} Sin ( \frac{( 2 n + 1 ) π r}{2 R} )\end{matrix} \qquad Equation 16$$

The electronic device may obtain a coefficient K based on Equation 17 below by applying an orthogonal condition (e.g., t=0) to Equation 16.

$${\int }_{r = 0}^{r = R} ( \frac{1}{r} ) ( Cs ( r , t = 0 ) - C {s}_{s} ( r ) ) Sin ( \frac{( 2 n + 1 ) π r}{2 R} ) {r}^{2} dr = {\sum }_{n = 1}^{∞} ( R {K}_{n} ) {\int }_{r = 0}^{r = R} ( \frac{1}{{r}^{2}} ) Sin ( \frac{( 2 n + 1 ) π r}{2 R} ) Sin ( \frac{( 2 m + 1 ) π r}{2 R} ) {r}^{2} d r \qquad Equation 17$$

In an example, in operation 230, the electronic device may determine the SoC value at the instance of interest by correlating the determined equilibrium ion-concentration value (Cs-s) and the transient ion-concentration profile. As described above with reference to operation 220, the ion-concentration value, Cs (r, t), may be expressed by Equation 18 below.

$$\begin{matrix}Cs ( r , t ) = steady state\_transient state \\ = {Cs}_{s} ( r ) + C {s}_{t} ( r , t )\end{matrix} \qquad Equation 18$$

$$Cs ( r , t ) = \frac{3}{{R}^{3}} {\int }_{r = 0}^{r = R} Cs ( r , t = 0 ) {r}^{2} dr + {\sum }_{n = 1}^{∞} ( \frac{R {K}_{n}}{r} ) {e}^{- ( \frac{{( ( 2 n + 1 ) π / 2 )}^{2} Dt}{{R}^{2}} )} Sin ( \frac{( 2 n + 1 ) π r}{2 R} )$$

Additionally, in an example, the electronic device may calculate an SoC value of the battery (e.g., the battery 100 of FIG. 1A), based on Equation 19 below.

$$\frac{\partial {U}_{k}}{\partial t} = \frac{\partial {U}_{k}}{\partial SO {C}_{k}} \frac{\partial SO {C}_{k}}{\partial t} + \frac{\partial {U}_{k}}{\partial {T}_{k}} \frac{\partial {T}_{k}}{\partial t} = \frac{\partial {U}_{k}}{\partial SO {C}_{k}} \frac{1}{{C}_{s , maxk}} \frac{\partial {C}_{s , k}}{\partial t} + \frac{\partial {U}_{k}}{\partial {T}_{k}} \frac{\partial {T}_{k}}{\partial t} \qquad Equation 19$$

The electronic device may consider a temperature change during the rest period of the battery to be zero by considering an actual usage of the battery. Additionally, in an example, the electronic device may calculate the SoC value of the battery of the instance of interest, based on Equation 20.

$$\frac{\partial {U}_{k}}{\partial t} = \frac{\partial {U}_{k}}{\partial SO {C}_{k}} \frac{1}{{C}_{s , max k}} \frac{\partial {C}_{s , k}}{\partial t} = A \frac{\partial {C}_{s , k}}{\partial t} \qquad Equation 20$$

$${U}_{k} = \frac{3 A}{{R}^{3}} {\int }_{r = 0}^{r = R} Cs ( r , t = 0 ) {r}^{2} dr + A {\sum }_{n = 1}^{∞} ( {K}_{n} ) {e}^{- ( \frac{{( 2 n + 1 )}^{2} {π}^{2} Dt}{4 {R}^{2}} )} Sin ( \frac{( 2 n + 1 ) {π}^{2}}{2} )$$

In Equation 20, U may denote an open circuit potential (OCP). In Equation 20, t may denote a time elapsing from the beginning of the rest period of the battery. In Equation 20, r may denote the radius of the surface of the particle (e.g., the particle 150 of FIG. 1B). In addition, R may denote the outer radius or maximum radius of the particle (e.g., the particle 150 of FIG. 1B). Next, Cs may denote an ion concentration on the surface of the particle. In addition, k may denote an electrode. Next, A may denote

$$\frac{\partial {U}_{k}}{\partial SO {C}_{k}} \frac{1}{{C}_{s , maxk}}$$

and Cₛₘₐₓ may denote the maximum value of the ion concentration. Finally, K may denote a harmonic constant obtained by applying the orthogonal condition.

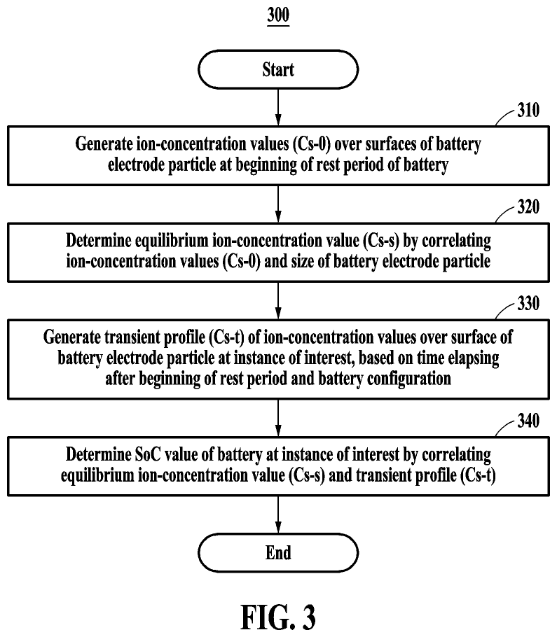

FIG. 3 illustrates an example method for an electronic device to determine a rest period SoC value of a battery at an instance of interest according to one or more embodiments.

Referring to FIG. 3, in a non-limiting example, a method 300 may include operations 310 to 340 of FIG. 3.

In an example, in operation 310, an electronic device (e.g., the electronic device 600 of FIG. 6) may generate an ion-concentration value (e.g., an initial ion-concentration value (Cs-0)) over surfaces of a particle (e.g., the particle 150 of FIG. 1B) of a battery at the beginning of a rest period of a battery (e.g., the battery 105 of FIG. 1A). In an example, in operation 320, the electronic device may determine an equilibrium ion-concentration value (Cs-s) by correlating ion-concentration values (e.g., the initial ion-concentration value (Cs-0)) and the size of the particle (e.g., the particle 150 of FIG. 1B) of the battery (e.g., the battery 105 of FIG. 1A). In an example, in operation 330, the electronic device may generate a transient profile (Cₛ₋ₜ) of ion-concentration values over the surface of the particle (e.g., the particle 150 of FIG. 1B) at the instance of interest, based on a time elapsing after the beginning of the rest period and the battery configuration. In an example, in operation 340, the electronic device may determine the SoC value of the battery at the instance of interest by correlating the equilibrium ion-concentration value (Cs-s) and the generated transient profile (e.g., the profile corresponding to the ion concentration value (Cₛ₋ₜ)).

For example, the rest period may be a period during which the battery is under an open rest condition (e.g., when the battery current is zero) or a float rest condition. For example, the electronic device may compare a current across terminals of the battery (e.g., the battery 100 of FIG. 1A) to a preset value to determine a rest period associated with the battery. The preset value may vary depending on the configuration of the battery. For example, the preset value may be 0.01 amperes, 0.005 amperes, and the like but is not limited thereto. The method 300 performed by the electronic device is described in detail with reference to the method 200.

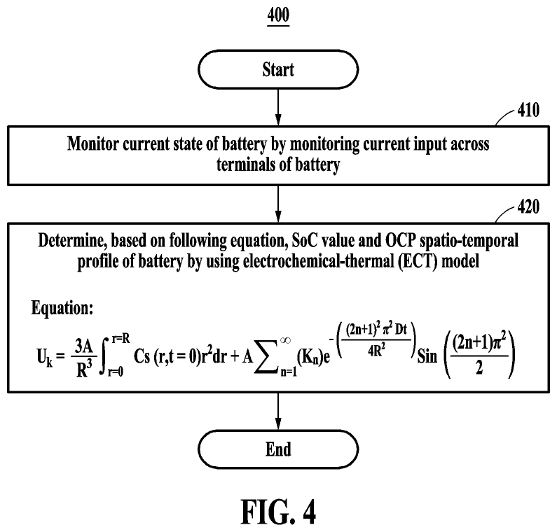

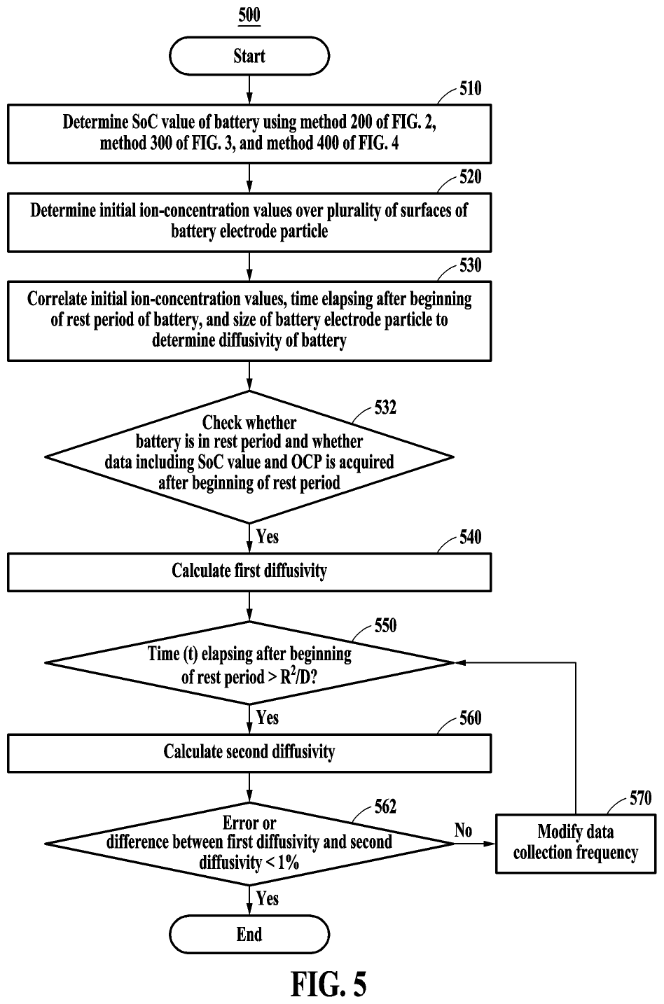

FIG. 4 illustrates an example method for an electronic device to determine an equilibrium SoC value according to one or more embodiments.

Referring to FIG. 4, in a non-limiting example, the method 400 may include operations 410 and 420.

In operation 410, the electronic device (e.g., the electronic device 600 of FIG. 6) may monitor a current state of a battery (e.g., the battery 105 of FIG. 1A) by monitoring a current input across terminals of the battery. For example, during a rest period of the battery, the inflow and/or outflow current flux of a particle (e.g., the particle 150 of FIG. 1B) may be essentially 0. Thus, the electronic device may be based on deriving an expression for a spatio-temporal profile of an ion concentration in the particle (e.g., the particle 150 of FIG. 1B). For example, the electronic device may derive an expression for an SoC value and an OCP of the battery (e.g., the battery 105 of FIG. 1A), based on solving a spherical-diffusion equation for a relevant BC.

Referring to FIG. 2, the electronic device may divide the above equations into profiles for equilibrium and transient states of the battery (e.g., the battery 105 of FIG. 1A). For example, the electronic device may express a transient concentration profile solution as a combination of a sum of sine harmonics in a spatial domain (e.g., the size or volume of the particle (e.g., the particle 150 of FIG. 1B)) and an exponential in a time domain (e.g., a time after the beginning of a rest period). In an example, in operation 420, the electronic device may determine an SoC value of the battery using an electrochemical-thermal (ECT) model, based on Equation 21 below derived from Equation 20 and may determine the OCP of the battery accordingly.

$${U}_{k} = \frac{3 A}{{R}^{3}} {\int }_{r = 0}^{r = R} Cs ( r , t = 0 ) {r}^{2} dr + A {\sum }_{n = 1}^{∞} ( {K}_{n} ) {e}^{- ( \frac{{( 2 n + 1 )}^{2} {π}^{2} D t}{4 {R}^{2}} )} Sin ( \frac{( 2 n + 1 ) {π}^{2}}{2} ) \qquad Equation 21$$

In Equation 21, U may denote an OCP. t may denote a time elapsing from the beginning of the rest period of the battery. In Equation 21, r may denote the radius of the surface of the particle (e.g., the particle 150 of FIG. 1B). In Equation 21, R may denote the outer radius or maximum radius of the particle (e.g., the particle 150 of FIG. 1B). In Equation 21, Cs may denote an ion concentration on the surface of the particle. Next, k may denote an electrode. In addition, A may denote

$$\frac{\partial {U}_{k}}{\partial SO {C}_{k}} \frac{1}{{C}_{s , maxk}} .$$

In addition, Cₛₘₐₓ may denote the maximum value of the ion concentration. Finally, K may denote a harmonic constant obtained by applying the orthogonal condition. For reference, the variables in Equation 21 are the same as those explained in Equation 20.

The electronic device may implement the ECT model, based on a BMS (e.g., the BMS 110 of FIG. 1) of the battery (e.g., the battery 105 of FIG. 1A). For example, the electronic device may be able to implement Equation 21, based on the BMS. In other words, the electronic device may implement the ECT model by adding a few lines of code to an ECT-ROM framework according to the comparative example of the BMS. For example, the electronic device may accurately estimate, based on the ECT model, an SoC value and an OCP during a rest period by evaluating the spatio-temporal profile of electrode concentration. For example, the electronic device may derive the ECT model from an electric charge/mass conservation-based spherical diffusion equation with a uniform BC with no flux at the center, surface, and initial conditions to derive the spatio-temporal evolution of electrode concentration.

The electronic device may configure the ECT model to determine ion-concentration values on the surface of an electrode particle (e.g., the particle 150 of FIG. 1B) of the battery (e.g., the battery 105 of FIG. 1A).

In an example, the electronic device may determine the OCP of the battery from a transient concentration profile such as a profile (e.g., the profile 120-t of FIG. 1C) corresponding to the transient ion-concentration values (Cₛ₋ₜ) of the battery and an equilibrium concentration profile such as a profile (e.g., the profile 120-Eq of FIG. 1B or the profile 120-Eq of FIG. 1C) corresponding to the equilibrium ion-concentration values (Cs-s). The electronic device may obtain a profile (e.g., the profile 120-Eq of FIG. 1B or the profile 120-Eq of FIG. 1C) and a profile (e.g., the profile 120-t of FIG. 1C) using an initial ion-concentration profile (e.g., the profile 120-2 of FIGS. 1B and 1C) corresponding to the ECT model and ion-concentration values of the battery.

FIG. 5 illustrates an example method for an electronic device to determine a diffusivity of a battery according to one or more embodiments.

Referring to FIG. 5, in a non-limiting example, the electronic device (e.g., the electronic device 600 of FIG. 6) may determine the diffusivity of a battery (e.g., the battery 105 of FIG. 1A), based on an SoC value of the battery determined using the method 200, the method 300, and the method 400 described above. For reference, a method 500 may include operations 510 to 530 of FIG. 5.

In an example, in operation 510, the electronic device may determine the SoC value of the battery (e.g., the battery 105 of FIG. 1A) using the method 200 of FIG. 2, the method 300 of FIG. 3, and the method 400 of FIG. 4. In an example, in operation 520, the electronic device may determine initial ion-concentration values over a plurality of surfaces of a battery electrode particle (e.g., the particle 150 of FIG. 1B).

In an example, in operation 530, the electronic device may correlate the initial ion-concentration values, a time elapsing after the beginning of a rest period of the battery, and the size of the particle (e.g., the particle 150 of FIG. 1B) to determine the diffusivity of the battery (e.g., the battery 105 of FIG. 1A). For reference, a rest period may correspond to a period during which a battery is under an open rest condition (e.g., when a battery current is zero) or a period during which the battery is under a float rest condition (e.g., when a predetermined battery terminal voltage is maintained).

The electronic device may derive Equation 22 corresponding to an OCP (e.g., Uₖ) from Equation 21 above.

$${U}_{k} ∝ {e}^{- ( \frac{{( 2 n + 1 / 2 )}^{2} {π}^{2} Dt}{{R}^{2}} )} \qquad Equation 22$$

In Equation 22, assuming that a considerable amount of time elapses, (t>>R²/D) and n=1 may be satisfied. Therefore, when a considerable amount of time elapses, an OCP value may satisfy Equation 23 below.

$${U}_{k} ∝ {e}^{- ( \frac{9 {π}^{2} D t}{4 {R}^{2}} )} \qquad Equation 23$$

Equation 23 may be expressed as Equation 24 below.

$${U}_{k} ∝ {e}^{- ( b t )} \qquad Equation 24$$

In this case, according to Equations 23 and 24, Equation 25 below may be derived.

$$D = \frac{4 {bR}^{2}}{9 {π}^{2}} \qquad Equation 25$$

In Equation 25, b may denote the slope of a profile between a time and a logarithm of an OCP.

In addition, the method 500 may further include operations 532 to 570.

In an example, in operation 532, the electronic device (e.g., the electronic device 600 of FIG. 6) may check whether the battery (e.g., the battery 105 of FIG. 1A) is in a rest period and whether data including an SoC value and the OCP is acquired after the beginning of the rest period. When determining that the battery is in a rest period and that the data including the SoC value and the OCP is acquired after the beginning of the rest period, the electronic device may calculate first diffusivity (e.g., D of Equation 25), based on Equation 25 in operation 540. Subsequently, in an example, in operation 550, the electronic device may determine whether the time elapsing after the beginning of the rest period is greater than a predetermined threshold value (e.g., R²/D).

In an example, the electronic device may include an iterative convergence loop in the method 500 to calculate diffusivity. For reference, diffusivity may be calculated with a preset accuracy and/or error. Therefore, in operation 560, the electronic device may calculate second diffusivity, based on Equation 25. The second diffusivity may also be referred to as real-time acquired diffusivity or latest diffusivity and may be diffusivity calculated more recently than the first diffusivity. In an example, in operation 562, the electronic device may compare the first diffusivity to the second diffusivity. In this case, the electronic device may iteratively calculate the second diffusivity, based on Equation 25 when the error or difference between the first diffusivity and the second diffusivity is greater than or equal to a preset value (e.g., 1%). In an example, in operation 570, the electronic device may modify data collection frequency depending on the difference between the second diffusivity (i.e., latest diffusivity) and the first diffusivity.

Therefore, the electronic device may determine the solid-state diffusivity of the battery (e.g., the battery 105 of FIG. 1A) from the temporal profile of the OCP using Equation 25.

FIG. 6 illustrates an example electronic device for determining an SoC value of a battery at an instance of battery according to one or more embodiments.

Referring to FIG. 6, in a non-limiting example, an electronic device 600 may include a plurality of processing elements 602 including a first processing element 610 for determining an equilibrium ion-concentration value (Cs-s) of the battery 105, a profile generation processing element 620 for generating a transient ion-concentration profile, such as a profile (e.g., the profile 120-t of FIG. 1C), at an instance of interest, and a correlating processing element 630.

In an example, the first 610 may determine the equilibrium ion-concentration value (Cs-s) by correlating the initial ion-concentration values (Cs-0) and the size (e.g., radius) of a particle (e.g., the particle 150 of FIG. 1B) at the beginning of a rest period of the battery 105. The initial ion-concentration value (Cs-0) may correspond to a plurality of surfaces of the particle. The profile generation processing element 620 may generate a transient ion-concentration profile over a plurality of surfaces, based on the configuration of the battery and initial ion-concentration values at the instance of interest. The correlating processing element 630 may determine an SoC at the instance of interest by correlating the determined equilibrium ion-concentration value (Cs-s) and the transient ion-concentration profile (e.g., the profile 120-t of FIG. 1C).

The electronic device 600 may include an operating condition processing element 640 configured to detect an operating condition of the battery 105 by comparing the current of the battery 105 to a preset current value. For example, the operating condition may be one of a rest condition of the battery 105, a charging condition of the battery 105, or a discharging condition of the battery 105.

The first processing element 610 may generate an initial ion-concentration profile, such as a profile (e.g., the profile 120-0 of FIG. 1B) of ion-concentration values over a plurality of surfaces of a battery electrode particle (e.g., the particle 150 of FIG. 1B). Additionally, the first processing element 610 may determine an average of the initial ion-concentration profile (e.g., the profile 120-0 of FIG. 1B) corresponding to the volume of the battery electrode particle (e.g., the particle 150 of FIG. 1B).

The first processing element 610 may generate an initial ion-concentration profile (e.g., the profile 120-0 of FIG. 1B) via the BMS 110 and correlate the size of the particle and the initial ion-concentration profile to determine an equilibrium ion-concentration value via the BMS 110.

Another profile generation processing element 620 may determine the diffusivity of the battery 105 and determine transient ion-concentration values over the plurality of surfaces by correlating the size of the battery 105 at the instance of interest, the determined diffusivity, the time elapsing after the beginning of a rest period, and the equilibrium ion-concentration value (Cs-s).

The plurality of processing elements 602 included in the electronic device 600 may include a diffusion correlation processing element 650. For example, the diffusion correlation processing element 650 may correlate the size of the particle (e.g., the particle 150 of FIG. 1B), the time elapsing after the beginning of the rest period of the battery 105, and the initial ion-concentration values to determine the diffusivity of the battery 105.

The electronic device 600 may perform the methods 200, 300, 400, and 500 described with reference to FIGS. 2 to 5, and the descriptions of the methods 200, 300, 400, and 500 are not repeated.

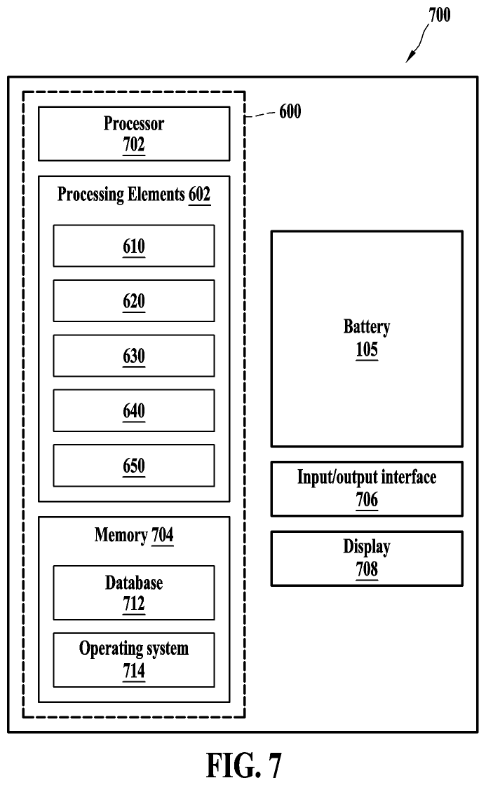

FIG. 7 illustrates an example electronic device according to one or more embodiments.

Referring to FIG. 7, in a non-limiting example, an electronic device 700 with battery SoC determination may be a device connected to a load (e.g., the load 130 of FIG. 1) of the battery 105, but examples are not limited thereto. The electronic device 700 may include an electric vehicle, an automobile, a motorcycle, a truck, and an electronic device using a rechargeable battery.

The electronic device 700 may include one or more processors 702, a memory 704, an input/output interface 706, a display 708, and the battery 105. For example, the memory 704 may store a database 712 and an operating system (OS) 714. The electronic device 700 may include a plurality of processing elements 602 (e.g., the plurality of modules 602 of FIG. 6). In FIG. 7, the input/output interface 706 and the display 708 are illustrated as being separate components, but the input/output interface 706 may include the display 708. The processor 702, the memory 704, the battery 105, the input/output interface 706, and the display 708 may be connected to one another by wire or wirelessly and transmit/receive data through communication with one another.

The electronic device 700 may be a system including the electronic device 600 of FIG. 6 including the processor 702, the plurality of modules 602, and the memory 704. In this case, the electronic device 600 may determine an SoC corresponding to the battery 105 at the instance of interest. The electronic device 600 may be included in the electronic device 700. Although not explicitly shown in FIG. 7, for example, one or more components of the electronic device 700 may be implemented via a cloud-based architecture or a physical server (not shown).

The processor 702 may be operatively coupled to the memory 704 and/or the plurality of processing elements 602 to process, execute, or perform a series of operations. For example, the processor 702 may include at least one data processor to perform an operation in a virtual storage area network. The processor 702 may further execute programs, and/or may control the electronic device 700 to perform one or more or all operations and/or methods involving the management of a battery, and may include any one or a combination of two or more of, for example, a central processing unit (CPU), a graphic processing unit (GPU), a neural processing unit (NPU) and tensor processing units (TPUs), but is not limited to the above-described examples. For example, the processor 702 may include one or more general processors, a digital signal processor (DSP), application-specific integrated circuits, field-programmable gate arrays (FPGAs), a server, a network, a digital circuit, an analog circuit, or a combination thereof. For example, the processor 702 may execute one or more instructions (e.g., manually generated (i.e., programmed) code) to perform one or more of the methods (e.g., the methods 200 to 500) disclosed herein. Thus, a duplicate description thereof is omitted herein.

The processor 702 may operate with the plurality of processing elements 602 to perform predetermined operations. In addition, the processing elements 602 may include processors and/or circuitry to respectively perform the functions described above. In an example, the processor 702 may include the processing elements 602 (e.g., one or more of the first processing element 610, the profile generation processing element 620, the correlating processing element 630, the operating condition processing element 640, and the diffusion correlation processing element 650). For example, the processor 702 may perform the methods 200, 300, 400, and 500 described with reference to FIGS. 2 to 5 by controlling the modules 602.

The processing elements 602 may perform a designated function together with the memory 704 and the processor 702. For example, the memory 704 may be communicatively coupled to the processor 702. For example, FIG. 7 illustrates the processing elements 602 and the memory 704 individually, but the processing elements 602 may be included in the memory 704.

The memory 704 may include computer-readable instructions. The processor 702 may be configured to execute computer-readable instructions, such as those stored in the memory 704, and through execution of the computer-readable instructions, the processor 702 is configured to perform one or more, or any combination, of the operations and/or methods described herein. The memory 704 may be a volatile or nonvolatile memory.

Other processing elements 602 may include a set of instructions executable by the electronic device 600. For example, the processing elements 602 may perform the methods 200, 300, 400, and 500 described with reference to FIGS. 2 to 5 using data stored in the memory 704. For example, the processing elements 602 may include a hardware device located outside the memory 704.

The memory 704 may include a volatile memory such as static random-access memory (SRAM) and dynamic random access memory (DRAM). Additionally, for example, the memory 704 may include a non-volatile memory, such as read-only memory (ROM), flash memory, a hard disk, an optical disk, and magnetic tape, and may include non-transitory computer-readable media. The memory 704 may be communicatively coupled to the processor 702 to store bitstreams or instructions for completing the methods 200, 300, 400, and 500 described with reference to FIGS. 2 to 5. Additionally, the memory 704 may store the OS 714 for the electronic device 700 to perform one or more tasks, as performed by a generic OS of a standalone device or a communication domain. The memory 704 may include a database 712 that stores information necessary for the processing elements 602 and the processor 702 to perform a method (e.g., the method 200 of FIG. 2, the method 300 of FIG. 3, the method 400 of FIG. 4, and the method 500 of FIG. 5) for determining an SoC value of the battery 105.

The memory 704 may store instructions executable by the processor 702. The functions, acts or tasks disclosed with reference to this specification and drawings may be performed by the processor 702 together with the processing elements 602 to perform instructions stored in the memory 704. For example, the functions, acts, or tasks may be independent of predetermined type of instruction set, a storage medium, a processor, or a processing strategy and may be performed by software, hardware, an integrated circuit, firmware, microcode, and the like, operating alone or in combination. Similarly, the processing strategy may include multiprocessing, multitasking, parallel processing, and the like.

The electronic device 700 may include one or more batteries 105. The battery 105 may correspond to a rechargeable Li-ion battery including one or more electrochemical cells. Each of one or more electrochemical cells may convert chemical energy into electrical energy through an electrochemical reaction. An external power source (e.g., the power supply device 101 of FIG. 1A) may be connected to the battery 105 to cause a plurality of electrons to flow from a positive electrode (e.g., a positive terminal) to a negative electrode (e.g., a negative terminal) in one or more electrochemical cells. At the same time, the electronic device 700 may complete the electrochemical reaction of the battery 105 by causing a plurality of ions to move from a cathode to an anode.

An input/output interface 706 (hereinafter, I/O interface 706) may be a hardware or software component that enables data communication between the electronic device 700 and any other device or system. For example, the I/O interface 706 may serve as a communication medium for exchanging information, a command, or data with other devices or systems.

The display 708 may include a display screen, a monitor, and a graphical user interface. The display 708 may be an output device that initially displays information to a user. For example, the display 708 may be a screen included in a computer, a smartphone, a mobile, a user device, a tablet, a television, and an automobile. The display 708 may render visual content and provide a user interface for interacting with the electronic device 700.

Additionally, the electronic device 700 may be a computer program product that performs instructions in response to a propagated signal. Additionally, an instruction may be transmitted or received via a network using a bus (not shown), an interface, or a communication port. The communication port or the interface may be part of the processor 702 or may be a separate component. The communication port may be generated in software or may be a physical connection in hardware. The communication port may be connected to a network, external media, an external display, or other components of the electronic device 600. The electronic device 700 may be connected to a network via a physical connection, such as a wired Ethernet connection, or may be connected wirelessly. Similarly, the electronic device 700 may have an additional physical connection or a wireless connection with other components of the electronic device 600.

The electronic device 700 may determine the SoC and diffusivity of the battery 105 through the methods 200, 300, 400, and 500 described with reference to FIGS. 2 to 5. The method in which the electronic device 700 accurately determines the SoC of the battery 105 is described above. For example, the electronic device 700 may apply a signature profile of an ion concentration of the rest period of the battery 105 over the surface of an electrode (particle) to ion-concentration profiles and correlate a value and a parameter already available in a BMS to determine the SoC value and diffusivity of the battery 105 without heavy computation or processing. Therefore, the load of the BMS may also be reduced. For example, the electronic device 700 may add code implemented based on Equations 20 and 25 to the existing ECT-ROM framework.

An on-board method of the BMS may still be used to determine an SoC value. Conversely, the electronic device 700 may obtain a modified SoC value, based on an SoC estimate value obtained from an ECT model according to a comparative example of the BMS. For example, the electronic device 700 may derive an expression corresponding to the spatio-temporal evolution of electrode concentration by developing an on-board ECT model from an electric charge/mass conservation equation using appropriate boundary and initial conditions.

A fundamental, physics-based electrochemical-thermal expression for diffusivity estimation derived from a first principle has been described above. The expression may be obtained by using a spatio-temporal profile of an OCP and using the expression up to the first harmonic for a time>diffusivity time scale (R2/D). In this time limit, the logarithm of the OCP change over time is found to be proportional to the diffusivity of the electrode. Therefore, the electronic device 700 may calculate the diffusivity, based on a profile slope between the logarithm of the OCP and the time.

The processors, memory, electronic devices, electronic apparatus, battery, battery apparatus 100, battery 105, power supply device 101, BMS 110, load 130, electronic device 600, the processing elements 302 including the first processing element 610, the profile generation processing element 620, the correlating processing element 630, the operating condition processing element 640, and the diffusion correlation processing element 650, electronic device 700, the processor 702, memory 704, database 712, operating system 714, input/output interface 706, and display 708 described herein and disclosed herein described with respect to FIGS. 1-7 are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-7 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RW, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method, the method comprising:
determining an equilibrium ion-concentration value of a battery by correlating initial ion-concentration values, at a beginning of a rest period of the battery, over a plurality of surfaces of a battery electrode particle of the battery, and a size of the battery electrode particle;
generating, at an instance of interest, a transient ion-concentration profile over the plurality of surfaces, based on a configuration of the battery and the initial ion-concentration values; and
determining a state of charge (SoC) of the battery at the instance of interest by correlating the equilibrium ion-concentration value and the transient ion-concentration profile.

2. The method of claim 1, wherein the determining of the equilibrium ion-concentration value of the battery comprises:
generating an initial ion-concentration profile of an ion concentration over the plurality of surfaces of the battery electrode particle.

3. The method of claim 2, wherein the determining of the equilibrium ion-concentration value of the battery comprises:
determining an average of the initial ion-concentration profile corresponding to a volume of the battery electrode particle.

4. The method of claim 1, wherein the determining of the equilibrium ion-concentration value of the battery comprises:
generating, via a battery management system (BMS) of the battery, an initial ion-concentration profile of ion-concentration values over the plurality of surfaces of the battery electrode particle at the beginning of the rest period of the battery; and
determining, via the BMS, the equilibrium ion-concentration value by correlating the size of the battery electrode particle and the initial ion-concentration profile.

5. The method of claim 1, wherein the generating of the transient ion-concentration profile comprises:
determining a diffusivity corresponding to the configuration of the battery; and
determining, at the instance of interest, transient ion-concentration values over the plurality of surfaces by correlating the size of the battery electrode particle, the diffusivity, an elapsed time after the beginning of the rest period, and the equilibrium ion-concentration value.

6. The method of claim 1, further comprising:
detecting an operating condition of the battery by comparing a current of the battery with a preset current value,
wherein the operating condition corresponds to one of a rest condition of the battery, a charging condition of the battery, and a discharging condition of the battery.

7. The method of claim 1, further comprising:
determining a rest period SoC of the battery at the instance of interest,
wherein the determining of the rest period SoC of the battery comprises:
generating, at the beginning of the rest period of the battery, ion-concentration values over a surface of the battery electrode particle;
determining the equilibrium ion-concentration value by correlating the ion-concentration values and the size of the battery electrode particle;
generating, at the instance of interest, a transient profile of the ion-concentration values over the surface of the battery electrode particle, based on a configuration of the battery and an elapsed time after the beginning of the rest period; and
determining the SoC of the battery at the instance of interest by correlating the generated transient profile and the equilibrium ion-concentration value.

8. The method of claim 1, further comprising:
determining an equilibrium SoC value in the rest period of the battery,
wherein the determining of the equilibrium SoC value comprises:
determining, at the beginning of the rest period of the battery, ion-concentration values over the surfaces of the electrode particle of the battery; and
determining the equilibrium SoC value by correlating sizes of the surfaces of the battery electrode particle and the ion-concentration values.

9. The method of claim 1, further comprising:
determining a diffusivity of the battery,
wherein the determining of the diffusivity of the battery comprises:
determining the initial ion-concentration values over the plurality of surfaces of the battery electrode particle; and
determining the diffusivity of the battery by correlating the initial ion-concentration values, an elapsed time after the beginning of the rest period of the battery, and a size of the battery electrode particle.

10. The method of claim 1, further comprising:
determining a diffusivity of the battery;
determining, based on a predetermined electrochemical-thermal (ECT) model, an open circuit potential (OCP) of the battery;
calculating a first diffusivity of the battery responsive to the battery being in the rest period at the instance of interest and the SoC and the OCP being obtained after the beginning of the rest period;
comparing an amount of time elapsed after the beginning of the rest period with a predetermined threshold value;
calculating a second diffusivity of the battery in response to the elapsed time being greater than the predetermined threshold value; and
changing a frequency of obtaining the SoC and the OCP in response to an error between the first diffusivity and the second diffusivity being greater than a preset value.

11. A non-transitory computer-readable storage medium storing instructions that, when executed by a processor, cause the processor to perform the method of claim 1.

12. An electronic device, the electronic device comprising:
processors configured to execute instructions; and
a memory storing the instructions, wherein execution of the instructions configures the processors to:
determine an equilibrium ion-concentration value of a battery by correlating initial ion-concentration values, at beginning of a rest period of the battery, over a plurality of surfaces of a battery electrode particle of the battery, and a size of the battery electrode particle;
generate, at an instance of interest, a transient ion-concentration profile over the plurality of surfaces, based on a configuration of the battery and the initial ion-concentration values; and
determine a state of charge (SoC) of the battery at the instance of interest by correlating the determined equilibrium ion-concentration value and the transient ion-concentration profile.

13. The electronic device of claim 12, wherein the determining the equilibrium ion-concentration value comprises:
generating an initial ion-concentration profile of ion-concentration values over the plurality of surfaces of the battery electrode particle.

14. The electronic device of claim 13, wherein the determining the equilibrium ion-concentration value comprises:
determining an average of the initial ion-concentration profile corresponding to a volume of the battery electrode particle.

15. The electronic device of claim 12, wherein the determining the equilibrium ion-concentration value comprises:
generating, via a battery management system (BMS) of the battery, an initial ion-concentration profile of the ion-concentration values over the plurality of surfaces of the battery electrode particle at the beginning of the rest period of the battery; and
determining the equilibrium ion-concentration value by correlating, via the BMS, the size of the battery electrode particle and the initial ion-concentration profile.

16. The electronic device of claim 12, wherein the generating the transient ion-concentration profile comprises:
determining a diffusivity corresponding to the configuration of the battery; and
determining, at the instance of interest, transient ion-concentration values over the plurality of surfaces by correlating the size of the battery electrode particle, the diffusivity, an elapsed time after the beginning of the rest period and the equilibrium ion-concentration value.

17. The electronic device of claim 12, wherein the processors are further configured to:
detect an operating condition of the battery by comparing a current of the battery with a preset current value, and
wherein the operating condition corresponds to one of a rest condition of the battery, a charging condition of the battery, and a discharging condition of the battery.

18. The electronic device of claim 12, wherein the determining the equilibrium ion-concentration value comprises:
generating, at the beginning of the rest period of the battery, ion-concentration values over a surface of the battery electrode particle; and
determining the equilibrium ion-concentration value by correlating the ion-concentration values and a size of the battery electrode particle,
wherein the generating the transient ion-concentration profile comprises:
generating, at the instance of interest, a transient profile of the ion-concentration values over the surface of the battery electrode particle, based on the configuration of the battery and an elapsed time after the beginning of the rest period,
wherein the determining the SoC comprises:
determining the SoC of the battery, at the instance of interest, by correlating the equilibrium ion concentration value and the transient profile, and
wherein processors are further configured to:
determine a rest period SoC of the battery at the instance of interest.

19. The electronic device of claim 12, wherein the determining the equilibrium ion-concentration value comprises:
determining ion-concentration values over surfaces of an electrode particle of the battery at the beginning of the rest period of the battery, and
wherein the determining the SoC comprises:
determining an equilibrium SoC in the rest period of the electronic device by correlating sizes of the surfaces of the battery electrode particle and the ion-concentration values.

20. The electronic device of claim 12, wherein the determining the equilibrium ion-concentration value comprises:
determining the initial ion-concentration values over a plurality of surfaces of the battery electrode particle, and
wherein the processors are further configured to:
determine a diffusivity of the battery by correlating the initial ion-concentration values, an elapsed time, and a size of the battery electrode particle.
